(19) United States
(12) Patent Application Publication
(10) Pub. No.: US 2015/0090987 A1
(43) Pub. Date: Apr. 2, 2015

(54) ORGANIC EL DISPLAY DEVICE

(71) Applicant: Japan Display Inc., Tokyo (JP)

(72) Inventor: Naoki UETAKE, Tokyo (JP)

(73) Assignee: Japan Display Inc.

(21) Appl. No.: 14/497,372

(22) Filed: Sep. 26, 2014

(30) Foreign Application Priority Data
Sep. 27, 2013 (JP) 2013-201401

(51) Int. Cl. H01L 27/32; H01L 51/52

(52) U.S. Cl. CPC H01L 27/322; H01L 51/5203
USPC 257/40

(57) ABSTRACT

An organic EL display device includes an organic layer having plural layers including a light emitting layer, and a color filter that passes a light of a predetermined wavelength region. The organic layer includes a first organic layer that is arranged in a first area having plural independent areas in a display area, and includes the light emitting layer that emits a light of a first wavelength region, and a second organic layer that is arranged in a second area having plural independent areas which is an area different from the first area in the display area, and includes the light emitting layer that emits a light of a second wavelength region which is different from the first wavelength region. The color filter has a first color filter and a second color filter that pass respective lights of different wavelength regions in the light emitted from the light emitting layer of the first organic layer.

The present application claims priority from Japanese patent application JP2013-201401 filed on Sep. 27, 2013, the content of which is hereby incorporated by reference into this application.

### BACKGROUND OF THE INVENTION

1. Field of the Invention

The present invention relates to an organic EL display device.

2. Description of the Related Art

In recent years, an image display device (hereinafter referred to as “organic EL (electroluminescent) display device”) using a self-luminous body called “organic light emitting diode (OLED)” has been put in practical use. As compared with a related-art liquid crystal display device, because the organic EL display device uses a self-luminous body, the organic EL display device is not only excellent in visibility and response speed, but also does not require an auxiliary lighting device such as backlight. As a result, the organic EL display device can be further thinned.

Color display in the organic EL display device of this type is mainly classified into two types of one case in which light emitting elements that emit respective lights of three colors of R (red), G (green), and B (blue) are provided in each of pixels, and the other case in which a light of white or the like is emitted in the light emitting element, and color filters of the respective pixels transmit the respective wavelength regions of three colors of RGB.

JP 2004-103532 A discloses a light emitting display device that conducts color display of two colors with the use of two different colors of light emitting elements. JP 2004-207217 A discloses an organic EL display device having an organic layer formed for each of pixels, independently, in which a contact hole of an upper electrode is formed within a display area, a resistance of the upper electrode is reduced, and a potential of an upper electrode is uniformized.

### SUMMARY OF THE INVENTION

The organic EL display device that emits the light of each single color of RGB requires a vapor deposition mask and a vapor deposition process dedicated for the respective three colors of RGB in a manufacturing process. However, because a precision of the vapor deposition process is lower than a precision of a photolithography process, a space between pixels (accurately, between sub-pixels) must increase, to thereby make high definition difficult, and reduce an aperture ratio. As a result, there is a tendency to lower the light emission efficiency. Also, when white is extracted from tandem light emitting elements, light emitting layers are laminated on each other to increase a necessary voltage, and only a necessary single color is extracted from white by the color filters. As a result, the light emission efficiency decreases to prevent the low power consumption.

The present invention has been made in view of the above-mentioned circumstances, and therefore aims at providing a light emitting element display device that can extract and display a light with the high light emission efficiency and the low power consumption.

According to the present invention, there is provided an organic EL display device, including: lower electrodes that are arranged for respective sub-pixels within a display area which are arranged in a matrix, made of a conductive material, and controlled in potential for the respective sub-pixels; an upper electrode that is arranged to cover the display area, and made of a conductive material; an organic layer that is arranged between the lower electrodes and the upper electrode, and formed of a plurality of layers including a light emitting layer; and a color filter that passes a light of a predetermined wavelength region, in which the organic layer includes: a first organic layer that is arranged in a first area having a plurality of independent areas in the display area, and includes the light emitting layer that emits a light of a first wavelength region; and a second organic layer that is arranged in a second area having a plurality of independent areas in the display area, and includes the light emitting layer that emits a light of a second wavelength region different from the first wavelength region, and in which the color filter has a first color filter and a second color filter that pass respective lights of different wavelength regions in the light emitted from the light emitting layer of the first organic layer.

Also, according to the present invention, the organic EL display device may further include a metal line that extends between the sub-pixels within the display area, in which the upper electrode comes in contact with the metal line through a contact hole.

Also, according to the present invention, in the organic EL display device, the light emitting layer of the first organic layer may emit a light including wavelength regions of green and red, and the light emitting layer of the second organic layer may emit a light including a wavelength region of blue.

Also, according to the present invention, in the organic EL display device, the first area may cover eight of the sub-pixels, and the second area may cover four of the sub-pixels.

### BRIEF DESCRIPTION OF THE DRAWINGS

FIG. 1 is a diagram schematically illustrating an organic EL display device according to a first embodiment of the present invention;

FIG. 2 is a diagram illustrating a configuration of an organic EL panel in FIG. 1;

FIG. 3 is a plan view illustrating an enlarged display area of a sealing substrate in the organic EL panel, which is a diagram illustrating a layout of color filters;

FIG. 4 is a cross-sectional view schematically illustrating the organic EL panel taken along a line IV-IV in FIG. 3;

FIG. 5 is a diagram illustrating a layout of a first organic layer and a second organic layer in a planar view of a TFT substrate;

FIG. 6 is a diagram illustrating a layout of a first organic layer and a second organic layer in a TFT substrate of an organic EL display device according to a second embodiment in the same view as that in FIG. 5;

FIG. 7 is a cross-sectional view schematically illustrating the organic EL panel taken along a line VII-VII in FIG. 6; and

FIG. 8 is a diagram illustrating a difference between an aperture ratio of the above-mentioned respective embodiments, and an aperture ratio in a case where an area of an organic layer is formed for each of colors of RGB in a related art.

### DETAILED DESCRIPTION OF THE INVENTION

Hereinafter, embodiments of the present invention will be described with reference to the accompanying drawings. In the drawings, identical or similar elements are denoted by the same symbols, and a repetitive description will be omitted.

### First Embodiment

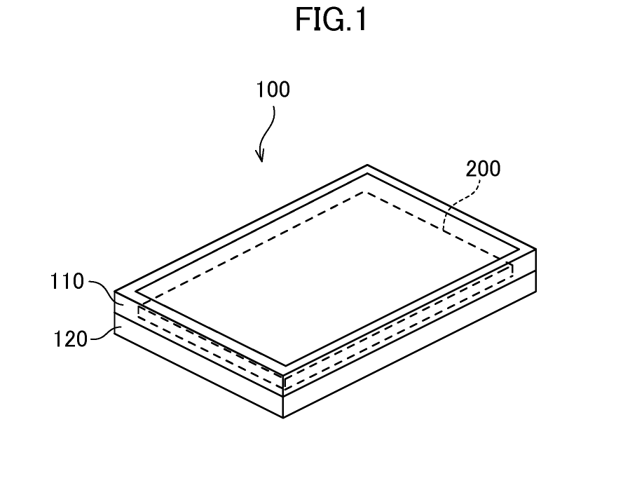

FIG. 1 schematically illustrates an organic EL display device 100 according to a first embodiment of the present invention. As illustrated in the figure, the organic EL display device 100 includes an organic EL panel 200 that is fixedly sandwiched between an upper frame 110 and a lower frame 120.

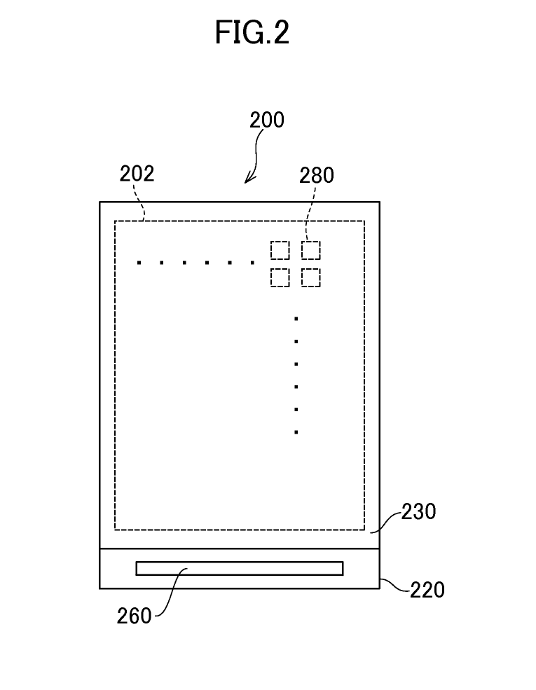

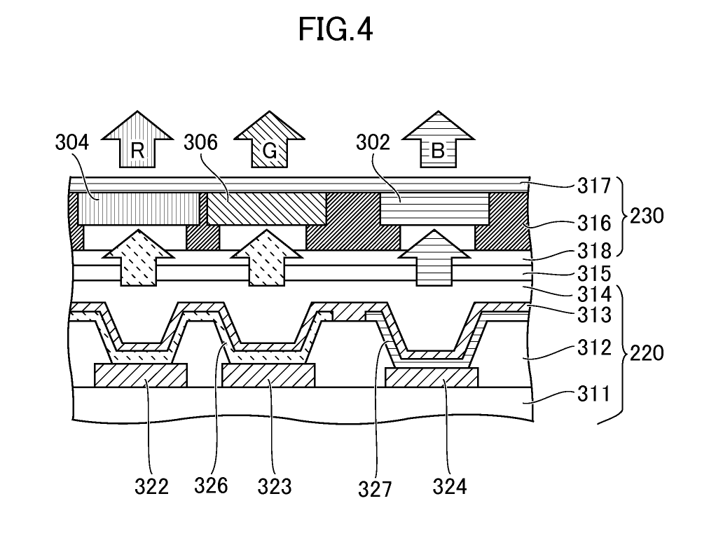

FIG. 2 illustrates a configuration of the organic EL panel 200 in FIG. 1. The organic EL panel 200 has two substrates of a TFT (thin film transistor) substrate 220, and a sealing substrate 230 that overlaps with the TFT substrate 220, and a space between those substrates is filled with a transparent resin 315 (refer to FIG. 4). The TFT substrate 220 has pixels 280 that are arranged in a display area 202 in a matrix. Also, on the TFT substrate 220 is placed a drive IC (integrated circuit) 260 that is a drive circuit which applies a potential for performing conduction between a source and a drain to scanning signal lines (not shown) of pixel transistors arranged in the respective pixels 280, and applies voltages corresponding to gradation values of the pixels 280 to data signal lines of the respective pixel transistors.

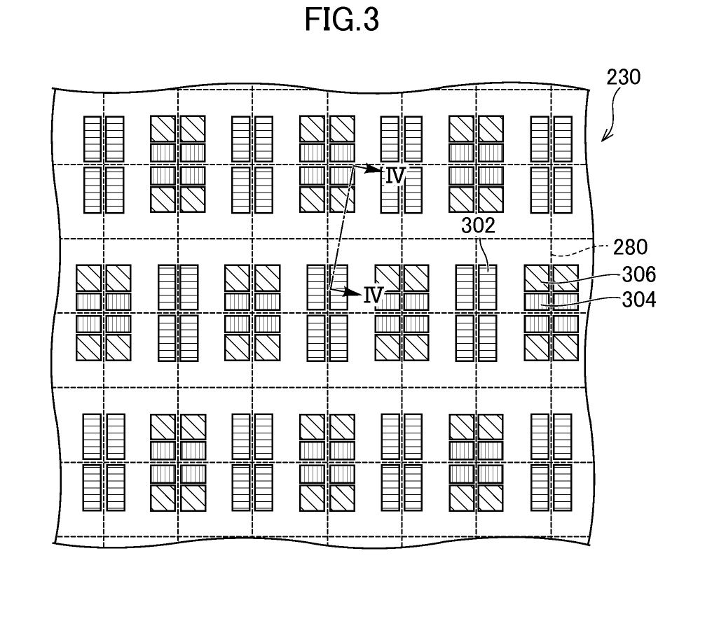

FIG. 3 is a plan view illustrating the enlarged display area 202 of the sealing substrate 230 in the organic EL panel 200, which is a diagram illustrating a layout of color filters. FIG. 4 is a cross-sectional view schematically illustrating the organic EL panel 200 taken along a line IV-IV in FIG. 3. As illustrated in FIGS. 3 and 4, an R (red) color filter 304, a G (green) color filter 306, and a B (blue) color filter 302 that transmit only light of wavelength regions of the respective corresponding colors are formed in the respective pixels 280 of the sealing substrate 230 to form R sub-pixels, G sub-pixels, and B sub-pixels, respectively.

As illustrated in FIG. 4, the TFT substrate 220 includes a planarizing film 311 that is made of an organic material and formed on a TFT circuit formed on an insulating substrate not shown, an R lower electrode 322, a G lower electrode 323, and a B lower electrode 324 which are formed on the planarizing film 311, and connected to the TFT circuit to be controlled in current, and an insulating bank 312 that is made of an insulating material, and formed between the respective sub-pixels to cover ends of each lower electrode. Also, the TFT substrate 220 includes a first organic layer 326 that includes a layer of plural organic materials having a light emitting layer which emits the light of a Y (yellow) color including wavelength regions of an R color and a G color, and is formed to come in contact with the R lower electrode 322 and the Glower electrode 323, and a second organic layer 327 that includes a layer of plural organic materials having a light emitting layer which emits the light of a B (blue) color, and is formed to come in contact with the B lower electrode 324. Further, the TFT substrate 220 includes an upper electrode 313 that comes in contact with the first organic layer 326 and the second organic layer 327, and is formed over an entire surface of the display area 202, and a protective film 314 that is made of an organic material, and formed on the upper electrode 313.

On the other hand, in the sealing substrate 230, the R color filter 304, the G color filter 306, and the B color filter 302 are formed on an insulating substrate 317 which is a glass substrate.

A black matrix 316 made of a material having a light blocking property is formed between respective color filters to prevent light from being output from between the respective pixels. Also, an overcoat layer 318 made of an organic material is formed to cover the respective color filters 302, 304, 306 and the black matrix 316. The TFT substrate 220 and the sealing substrate 230 adhere to each other with the transparent resin 315.

The light emitting layers of the first organic layer 326 and the second organic layer 327 emit light when holes or electrons injected from the respective lower electrodes 322, 323, and 324 are recoupled with electrons or holes injected from the upper electrode 313, an excited state is formed, and shifted to a ground state. As indicated by arrows in FIG. 4, the amount of light emission is controlled by the R lower electrode 322, and the Y color light emitted from the first organic layer 326 passes through the R color filter 304, and is emitted as the R color light. Also, the amount of light emission is controlled by the G lower electrode 323, and the Y color light emitted from the first organic layer 326 passes through the G color filter 306, and is emitted as the G color light. The amount of light emission is controlled by the B lower electrode 324, and the B color light emitted from the second organic layer 327 passes through the B color filter 302, and is emitted as the B color light. In this example, in the pixel of the B color filter 302, because the light emitted by the second organic layer 327 has already been a light having the wavelength region of the B color, a gray or transparent color filter may be used.

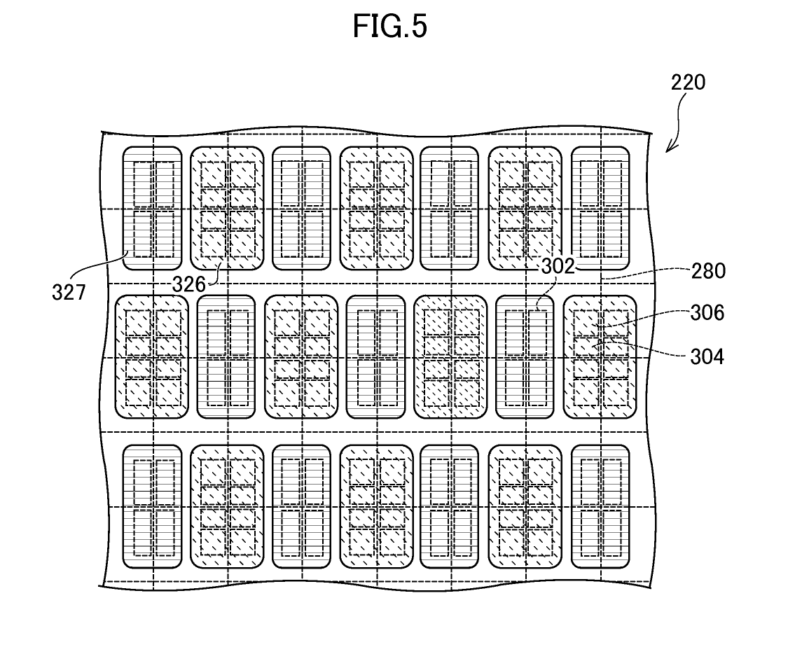

FIG. 5 is a diagram illustrating a layout of the first organic layer 326 and the second organic layer 327 in a planar view of the TFT substrate 220. As illustrated in FIG. 5, the R color filter 304, the G color filter 306, and the B color filter 302 are arranged in each of the pixels 280 one by one, and the plural first organic layers 326 and the plural second organic layer 327 are arranged cross the respective pixels 280. More specifically, the first organic layer 326 has plural areas each emitting light to the R color filters 304 and the G color filters 306 of four pixels 280, that is, eight sub-pixels in total. Also, the second organic layer 327 has plural areas each emitting light to the B color filters 302 of the four pixels 280, that is, four sub-pixels in total.

With the above arrangement, the organic layer can be formed by one area into which plural sub-pixels such as the four sub-pixels or the eight sub-pixels are put together. In general, because the organic layer is formed by vapor deposition, definition is difficult, and the organic layer for the plural sub-pixels is formed together. As a result, the intervals between the respective sub-pixel of the same organic layer can be shortened. Also, because only two kinds of organic layers are provided per pixel, an area required between the different organic layers can be reduced, and the aperture ratio of the respective sub-pixels can increase.

Also, because two kinds of the first organic layer 326 having the wavelength regions of the R color and the G color, and the second organic layer 327 having the wavelength region of the B color are configured to cover the display area 202, the power consumption can be suppressed as compared with a case in which the light of W (white) color having all of the wavelength regions of RGB is emitted over the overall display area. Also, in the design of the light emitting layer, the high efficient light emission can be conducted by designing a thickness (optical path length) of the light emitting layer forming such an optical path length as to intensify the color output by allowing the respective reflected lights in the respective lower electrodes 322 to 324 to resonance with a direct light that travels directly toward the color filters. However, as compared with a case in which the light of W is emitted over the entire surface, the optical path lengths specialized in only R and G, and the optical path length specialized in B can be designed, separately. For that reason, the degree of freedom of design can be increased, and the higher efficient light emission can be designed. That is, because those light emitting elements can be optimized, individually, the elements high in color purity, high in efficiency, and long in lifetime can be provided.

### Second Embodiment

A description will be given of an organic EL display device according to a second embodiment of the present invention. An overall configuration of the organic EL display device according to the second embodiment is identical with that illustrated in FIGS. 1 and 2 of the first embodiment, and therefore a repetitive description will be omitted.

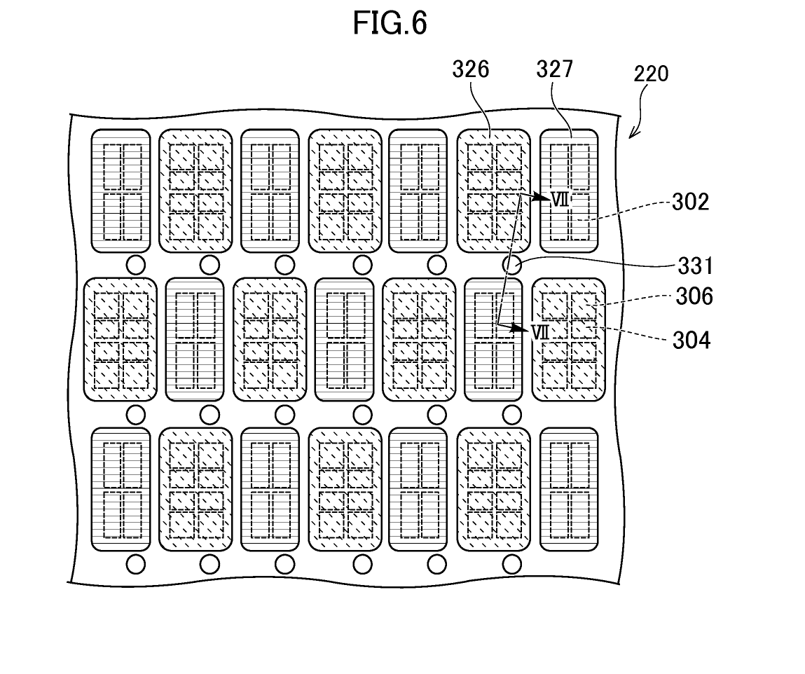

FIG. 6 is a diagram illustrating a layout of the first organic layer 326 and the second organic layer 327 in the TFT substrate 220 of the organic EL display device according to the second embodiment, in the same view as that in FIG. 5. As illustrated in FIG. 6, the organic EL display device according to the second embodiment is different from the organic EL display device according to the first embodiment in that an upper electrode contact hole 331 is formed.

When the upper electrode contact hole is to be formed in the organic EL panel where the organic layer is formed on the overall surface of the display area, there is a need to open a hole when the organic layer is formed with the use of a vapor deposition mask. As a result, the number of processes increases. However, because the first organic layer 326 and the second organic layer 327 in this embodiment do not cover the overall display area 202, the upper electrode contact hole 331 is formed with the use of an area in which those organic film films are not formed, and the upper electrode 313 can be connected to a line 329 formed in the TFT circuit.

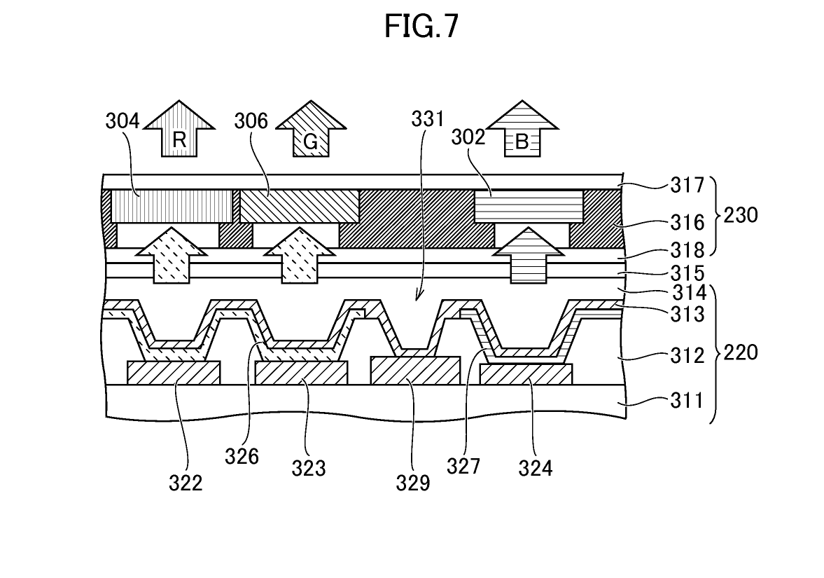

FIG. 7 is a cross-sectional view schematically illustrating the organic EL panel taken along a line VII-VII in FIG. 6. As illustrated in FIG. 7, the upper electrode 313 is connected to the line 329 formed in the TFT circuit in the upper electrode contact hole 331. In order to improve the transmittance of light, it is desirable that the upper electrode 313 is more thinly formed. However, a resistance value increases more as the upper electrode 313 becomes thinner, as a result of which a voltage drop is generated, an uneven brightness is likely to be generated between an end and the center of the display area 202. In particular, in the case of a large screen, because a distance between the center and the end of the display area 202 is longer, a difference in voltage is likely to be generated. In this embodiment, as illustrated in FIG. 6, because the organic layer does not cover the overall surface of the display area 202, the upper electrode contact hole 331 can be formed between the respective organic layers, and can be connected to the line 329 high in conductivity. With the above configuration, because the potential of the upper electrode 313 can be uniformized over the overall area of the display area 202, the excellent image can be displayed.

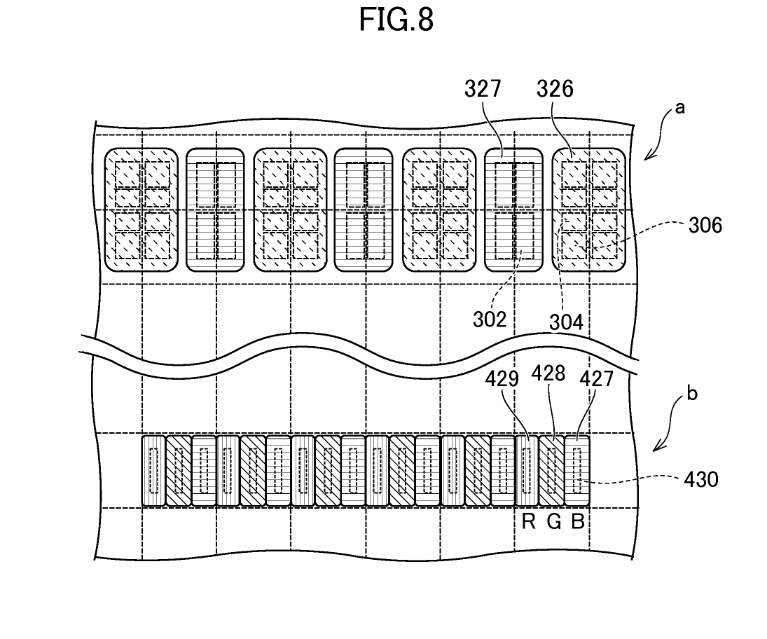

FIG. 8 is a diagram illustrating a difference between an aperture ratio of the above-mentioned respective embodiments, and an aperture ratio in a case where an area of an organic layer is formed for each of colors of RGB in a related art. A size of the light emission area in the above embodiment is substantially identical with a size of the color filters, and as indicated by “a” in FIG. 8, the sizes of the B color filter 302, the R color filter 304, and the G color filter 306 match the size of opening portions. On the other hand, when the organic layer is formed for each color of RGB, as indicated by “b”, respective light emitting areas 430 in an R organic layer 427, a G organic layer 428, and a B organic layer 429 match the opening portions. As those opening portions are compared with each other, it is found that the aperture ratio in the example of “a” according to this embodiment is clearly larger than the other aperture ratio.

Because the intervals of the light emitting areas of the different organic layers adjacent to each other depend on a precision in the vapor deposition, the size of the area that is not available as the opening portion is different between a case of “b” having three vapor deposition areas in one pixel, and a case of “a” having two vapor deposition areas in four pixels according to this embodiment. Therefore, according to the above respective embodiments, the aperture ratio can increase, the manufacture can be facilitated, and the higher definition can be conducted.

In the above-mentioned respective embodiments, the first organic layer having the light emitting layer of R+G or Y, and the second organic layer having the light emitting layer of B can be used. Alternatively, the combination of other colors such as the combination of R and C (cyan), or the combination of G and M (magenta) can be used. In this case, the light emitting layer may be multi-layered to emit a light including a desired wavelength region.

Also, in the above respective embodiments, the light emitting element display device is of a top emission system, but may be of a bottom emission system. Also, the light emitting layer is formed of a light emitting element classified into a so-called organic EL, but may be formed of the other self-luminous element that self-emits light.

Also, in the above-mentioned respective embodiments, the color filters are arranged on the sealing substrate. Alternatively, the color filters may be formed on the TFT substrate.

While there have been described what are at present considered to be certain embodiments of the invention, it will be understood that various modifications may be made thereto, and it is intended that the appended claims cover all such modifications as fall within the true spirit and scope of the invention.

What is claimed is:

1. An organic EL display device, comprising:
lower electrodes that are arranged for respective sub-pixels within a display area which are arranged in a matrix, made of a conductive material, and controlled in potential for the respective sub-pixels;
an upper electrode that is arranged to cover the display area, and made of a conductive material;
an organic layer that is arranged between the lower electrodes and the upper electrode, and formed of a plurality of layers including a light emitting layer; and
a color filter that passes a light of a predetermined wavelength region,
wherein the organic layer includes:
a first organic layer that is arranged in a first area having a plurality of independent areas in the display area, and includes the light emitting layer that emits a light of a first wavelength region; and
a second organic layer that is arranged in a second area having a plurality of independent areas in the display area, and includes the light emitting layer that emits a light of a second wavelength region which is different from the first wavelength region, and
wherein the color filter has a first color filter and a second color filter that pass respective lights of different wavelength regions in the light emitted from the light emitting layer of the first organic layer.

2. The organic EL display device according to claim 1, further comprising: a metal line that extends between the sub-pixels within the display area,
wherein the upper electrode comes in contact with the metal line through a contact hole.

3. The organic EL display device according to claim 1,
wherein the light emitting layer of the first organic layer emits a light including wavelength regions of green and red, and
wherein the light emitting layer of the second organic layer emits a light including a wavelength region of blue.

4. The organic EL display device according to claim 1,
wherein the first area covers eight of the sub-pixels.

5. The organic EL display device according to claim 1,
wherein the second area covers four of the sub-pixels.
